(19) United States
(12) Patent Application Publication
(10) Pub. No.: US 2026/0205081 A1
(43) Pub. Date: Jul. 16, 2026

(54) OPERATIONAL AMPLIFIER

(71) Applicant: ROHM CO., LTD., Kyoto-shi (JP)

(72) Inventor: Naohiro NOMURA, Kyoto-shi (JP)

(21) Appl. No.: 19/450,043

(22) Filed: Jan. 15, 2026

(30) Foreign Application Priority Data
Jan. 15, 2025 (JP) 2025-005784

(51) Int. Cl. H03F 3/45; G05F 1/56

(52) U.S. Cl. CPC H03F 3/45475; G05F 1/56

(57) ABSTRACT

An input stage includes a differential pair and an active load. An output stage includes an output transistor coupled to receive an output signal of the input stage. An output variation detection circuit is connected to an output terminal of an operational amplifier and generates a first current corresponding to an output voltage generated at the output terminal. A phase compensation circuit supplies, to the output terminal, a second current corresponding to a gate voltage of the output transistor, and supplies, to the active load, a third current corresponding to the second current.

### CROSS REFERENCE TO RELATED APPLICATIONS

The present invention claims priority under 35 U.S.C. § 119 to Japanese Application No. 2025-005784, filed on Jan. 15, 2025, the entire contents of which being incorporated herein by reference.

### BACKGROUND

### 1. Technical Field

This disclosure relates to an operational amplifier.

### 2. Description of the Related Art

Operational amplifiers are among the most important fundamental components in analog circuits. They are used as amplifiers for small-signal and large-signal applications, buffer circuits, regulators, and also as error amplifiers in feedback systems.

In conventional operational amplifiers designed for small-signal amplification applications, a capacitive load causes a phase delay. Depending on the amplifier type, oscillation or poor settling behavior often occurs with a capacitive load on the order of several hundred picofarads.

In some applications, such as reference-voltage source buffers and low-dropout (LDO) amplifiers, steep voltage variations or transient current loads are applied to the output. A large capacitance on the order of microfarads is coupled to the output to stabilize the output voltage in such cases, and high tolerance to a large load capacitance is required.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures.

FIG. 1 is a circuit diagram of an operational amplifier according to a comparative technique.

FIG. 2 is a circuit diagram of a non-inverting amplifier using the operational amplifier.

FIG. 3 is a diagram showing frequency characteristics of gain and phase of the non-inverting amplifier of FIG. 2.

FIG. 4 is a circuit diagram of an operational amplifier according to one embodiment.

FIG. 5 is a diagram showing frequency characteristics of a conventional non-inverting amplifier.

FIG. 6 is a circuit diagram of a non-inverting amplifier using an operational amplifier.

FIG. 7 is a diagram showing frequency characteristics of the non-inverting amplifier of FIG. 6.

FIG. 8 is a diagram showing frequency characteristics of a second current Is and a third current Ifb.

FIG. 9 is a diagram showing frequency characteristics of the output voltage of the non-inverting amplifier according to the comparative technology and the non-inverting amplifier according to the embodiment, respectively.

FIG. 10 is a circuit diagram of an operational amplifier according to Embodiment 1.

FIG. 11 is a circuit diagram of an operational amplifier according to Embodiment 2.

FIG. 12 is a circuit diagram of an operational amplifier according to Embodiment 3.

FIG. 13 is a circuit diagram of an operational amplifier according to Embodiment 4.

FIG. 14 is a circuit diagram of an operational amplifier according to Embodiment 5.

FIG. 15 is a circuit diagram of an operational amplifier according to Embodiment 6.

FIG. 16 is a circuit diagram of an operational amplifier according to Embodiment 7.

FIG. 17 is a circuit diagram of an offset-cancellation circuit according to one embodiment.

FIG. 18 is a diagram illustrating an operation of the offset-cancellation circuit of FIG. 17.

FIG. 19 is a diagram showing a relationship between a common-mode input voltage and an offset voltage of a non-inverting amplifier.

FIG. 20 is a diagram showing frequency characteristics of a non-inverting amplifier using the operational amplifier.

FIG. 21 is a circuit diagram of an offset-cancellation circuit according to a first modification.

FIG. 22 is a circuit diagram of an offset-cancellation circuit according to a second modification.

### DETAILED DESCRIPTION

### Overview of the Embodiments

An outline of several example embodiments of the disclosure follows. This outline is provided for the convenience of the reader to provide a basic understanding of such embodiments and does not wholly define the breadth of the disclosure. This outline is not an extensive overview of all contemplated embodiments and is intended to neither identify key or critical elements of all embodiments nor to delineate the scope of any or all aspects. Its sole purpose is to present some concepts of one or more embodiments in a simplified form as a prelude to the more detailed description that is presented later. For convenience, the term “one embodiment” may be used herein to refer to a single embodiment or multiple embodiments of the disclosure.

An operational amplifier according to one embodiment includes an input stage having a differential pair and an active load, an output stage including an output transistor coupled to receive an output signal of the input stage, an output variation detection circuit connected to an output terminal of the operational amplifier and configured to generate a first current corresponding to an output voltage generated at the output terminal, and a phase compensation circuit configured to supply, to the output terminal, a second current corresponding to a gate voltage of the output transistor and to supply, to the active load, a third current corresponding to the second current.

By the output variation detection circuit, a current signal (a first current) indicating a change in an output voltage caused by a gain peak in the frequency domain is generated. Then, by supplying, to the output terminal, a second current corresponding to the first current, the influence of the first current is canceled. Further, by supplying the active load, a third current corresponding to the first current, negative feedback is applied so as to suppress the change in the output voltage caused by the gain peak. As a result, the gain peak can be suppressed and phase rotation can be reduced, thereby improving stability with respect to a capacitive load.

As used herein, a statement that a signal A “corresponds to” a signal B means that the signal A has a correlation with the signal B, and it is sufficient that the correlation has a form and a degree that allow an effect of the invention to be achieved. For example, the signal A may have a positive correlation with the signal B or may have a negative correlation with the signal B and may be inverted depending on a circuit configuration. Further, the signal A may vary linearly with respect to the signal B or may vary nonlinearly with respect to the signal B.

In one embodiment, the active load may include a current mirror circuit and a pair of resistors connected to a source side of the current mirror circuit, and the third current may be supplied to a source side of the current mirror circuit.

In one embodiment, the active load may include a current mirror circuit and a pair of resistors connected to a source side of the current mirror circuit, and the third current may be supplied to a drain side of the current mirror circuit.

In one embodiment, the phase compensation circuit may be structured to be capable of adjusting an amount of the third current with respect to an amount of the second current. By optimizing the amount of the third current, a gain peak can be suitably suppressed.

In one embodiment, the phase compensation circuit may include a replica transistor of the same type as the output transistor, having its gate connected to a gate of the output transistor and having a source grounded, and a current source connected to a drain of the replica transistor. The phase compensation circuit may generate the second current and the third current in accordance with a drain voltage of the replica transistor.

In one embodiment, the phase compensation circuit may include a first transistor having a gate configured to receive a drain voltage of the replica transistor and having a source grounded, and a first current mirror circuit configured to mirror a current flowing through the first transistor to generate the second current.

In one embodiment, the phase compensation circuit may include a second transistor having a gate configured to receive a drain voltage of the replica transistor and having a source grounded, and a second current mirror circuit configured to mirror a current flowing through the second transistor to generate the third current.

In one embodiment, the output variation detection circuit may include a resistor provided between an output terminal of the operational amplifier and a ground line, or between the output terminal of the operational amplifier and a power supply line.

In one embodiment, the operational amplifier may further include an offset cancellation circuit configured to supply, to the active load, a correction current corresponding to an input voltage. With this configuration, a DC offset caused by a DC component of the third current supplied to the active load by the phase compensation circuit can be canceled.

In one embodiment, the offset cancellation circuit may include a common-mode voltage detection circuit configured to convert an input voltage of the operational amplifier into a current signal, and a correction current generation circuit configured to generate a correction current corresponding to the current signal.

In one embodiment, the common-mode voltage detection circuit may include a first MOS transistor and a second MOS transistor having gates connected to an input terminal of the operational amplifier, sources connected to each other, and drains connected to each other, and a third MOS transistor connected to the sources of the first MOS transistor and the second MOS transistor and having a gate supplied with a bias voltage common to a tail current source. When a common-mode input voltage changes, a source voltage of the first MOS transistor, in other words, a drain-to-source voltage of the third MOS transistor, changes. Accordingly, due to a channel length modulation effect, a current flowing through the third MOS transistor changes substantially linearly with respect to the input voltage.

In one embodiment, the correction current generation circuit may include a current mirror circuit connected to drains of the first MOS transistor and the second MOS transistor and configured to mirror a current flowing through the third MOS transistor, and a constant current source. The correction current may correspond to a difference between a current generated by the constant current source and an output current of the current mirror circuit.

In one embodiment, the operational amplifier may be monolithically integrated on a single semiconductor substrate. The term “monolithically integrated” includes a case in which all circuit components are formed on the semiconductor substrate and a case in which main circuit components are monolithically integrated, and some resistors, capacitors, or the like for adjusting circuit constants may be provided outside the semiconductor substrate.

### Comparative Technology

First, comparative technology will be described, and problems occurring in a conventional operational amplifier will be explained.

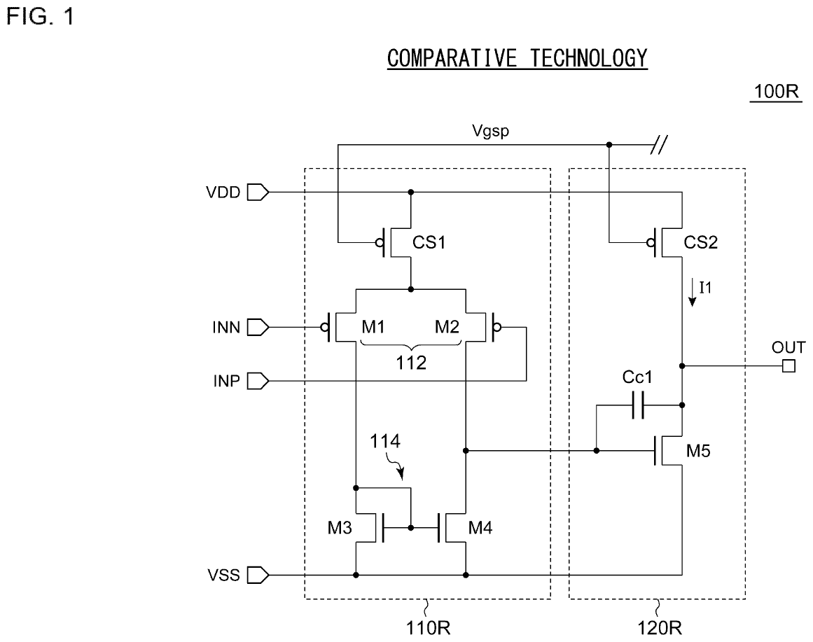

FIG. 1 is a circuit diagram of the operational amplifier 100R according to comparative technology.

The operational amplifier 100R includes an input stage 110R and an output stage 120R. The input stage 110R includes a differential pair 112, a tail current source CS1, and an active load 114. The differential pair 112 includes differential transistors M1 and M2. The tail current source CS1 supplies a tail current to the differential pair 112. The tail current source CS1 includes a PMOS transistor, and a bias voltage Vgsp is supplied to a gate of the PMOS transistor. The bias voltage Vgsp is a gate voltage of a PMOS transistor that is provided on a constant-current path and has its gate and drain short-circuited. The active load 114 includes transistors M3 and M4 forming a current mirror circuit.

The output stage 120R is of class-A type and includes an output transistor M5 and a current source CS2.

The output transistor M5 has its source grounded and receives an output signal of the input stage 110R at its gate.
The output transistor M5 is biased by a current I₁ generated by a current source CS5. A phase-compensation capacitor Cc1 is connected between a gate and a drain of the output transistor M5.

The operational amplifier 100R has a pole (referred to as a first pole ω1) formed by a composite resistance ro1 of resistances rd2 and rd4 of transistors M2 and M4 and the phase-compensation capacitor Cc1. At frequencies higher than the first pole ω1, a gain attenuates at −6 dB/Oct and a phase is delayed by 90 degrees.

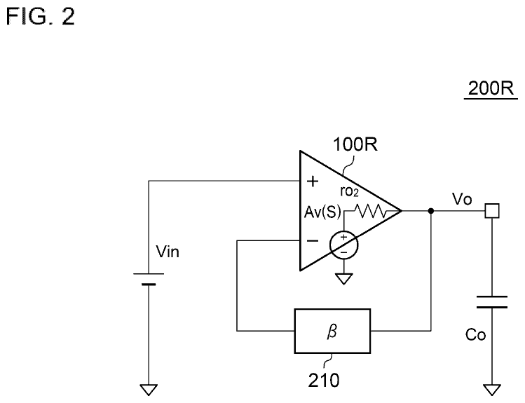

FIG. 2 is a circuit diagram of a non-inverting amplifier 200R using the operational amplifier 100R. The non-inverting amplifier 200R includes the operational amplifier 100R and a feedback circuit 210. β represents a feedback factor of the feedback circuit 210.

When a capacitive load (load capacitance Co) is connected to an output of the non-inverting amplifier 200R, a second pole (a second pole ω2) is formed by the load capacitance Co and an output impedance ro2 of the operational amplifier 100R. At frequencies higher than the second pole ω2, a gain attenuates at −12 dB/Oct and a phase is further delayed by 90 degrees.

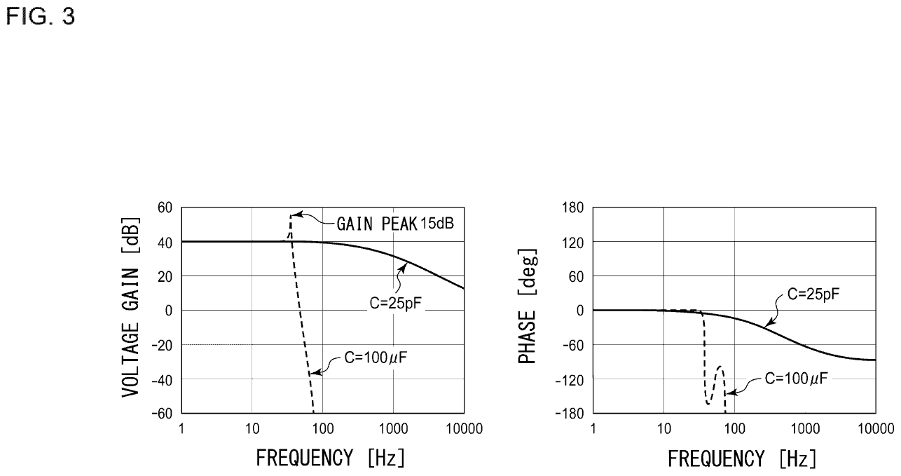

FIG. 3 is a diagram showing frequency characteristics of a gain and a phase of the non-inverting amplifier 200R of FIG. 2. FIG. 3 shows frequency characteristics when 25 pF and 100 μF are connected as a load capacitance Co. As the load capacitance Co increases, a second pole ω2 becomes close to a first pole ω1, which causes a steep gain attenuation and a rapid phase rotation. Then, a gain margin becomes small, and when the Barkhausen oscillation condition is satisfied, the system becomes unstable, which causes oscillation, poor settling, and the like. The load capacitance Co also causes a large gain peak.

In a conventional general operational amplifier 100R, depending on the design, when a load capacitance of several hundred pF to several nF order is connected, the system becomes unstable. Specifically, at power-on, an output voltage oscillates or a time required to settle becomes long.

Hereinafter, an operational amplifier improved in stability against a capacitive load will be described.

### Embodiment

Preferred embodiments will be described below with reference to the drawings. Like or equivalent components, members, and processes shown in the drawings are denoted by like reference numerals, and duplicated descriptions are omitted as appropriate. Further, embodiments are illustrative rather than limiting the present disclosure, and not all features or combinations described in the embodiments are necessarily essential to the disclosure.

In this specification, the expression “member A is connected to member B” includes not only a case in which member A and member B are physically and directly connected but also a case in which member A and member B are indirectly connected via another member that does not substantially affect their electrical connection state or does not impair a function or effect achieved by their coupling.

Similarly, the expression “member C is connected (provided) between member A and member B” includes not only a case in which member A and member C, or member B and member C are directly connected but also a case in which they are indirectly connected via another member that does not substantially affect their electrical connection state or does not impair a function or effect achieved by their coupling.

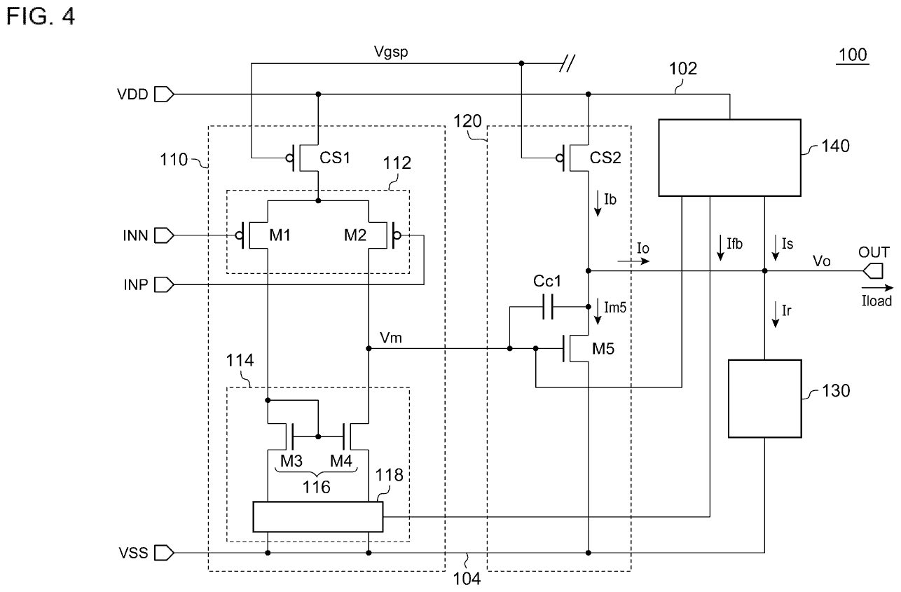

FIG. 4 is a circuit diagram of an operational amplifier according to an embodiment. The operational amplifier includes an input stage, an output stage, an output variation detection circuit, and a phase compensation circuit. A power supply voltage VDD is supplied to a power supply line, and a ground voltage VSS is supplied to a ground line.

The input stage 110 includes a differential pair 112, an active load 114, and a tail current source CS1. The differential pair 112 includes differential transistors M1 and M2 that are P-channel MOSFETs (Metal Oxide Semiconductor Field Effect Transistors). The tail current source CS1 includes a PMOS transistor to which a bias voltage Vgsp is supplied so that a constant current flows. Specifically, the bias voltage Vgsp is a gate voltage of a PMOS transistor that is provided on a constant-current path and has its gate and drain short-circuited.

The active load 114 is connected to drains of the differential pair 112. The active load 114 includes a current mirror circuit 116 formed by transistors M3 and M4.

An impedance circuit 118 is connected to a source side of the current mirror circuit 116. The impedance circuit is supplied with a third current Ifb described below, converts the third current Ifb into a voltage, and changes a balance of the current mirror circuit.

The output stage 120 includes an output transistor M5, a current source CS2, and a phase-compensation capacitor Cc1. The output transistor M5 is an N-channel MOSFET, has its source connected to the ground line 104 and its drain connected to the current source CS2. An output voltage Vm of the input stage 110 is supplied to a gate of the output transistor M5.

The output variation detection circuit generates a current corresponding to an output voltage of the operational amplifier, which is referred to as a first current Ir. The output variation detection circuit can be regarded as a V/I (voltage-to-current) conversion circuit having a conversion gain of 1/Ro, and the following relationship is established between the first current Ir and the output voltage Vo:

Ir=Vo/Ro

The first current Ir may include an alternating-current (AC) component and a direct-current (DC) component of the output voltage Vo. However, for simplicity of explanation, the latter is ignored, and the first current Ir can be regarded as representing an AC component of the output voltage Vo, in other words, a variation of the output voltage Vo.

A gate voltage of the output transistor, in other words, an output voltage of the input stage, is input to the phase compensation circuit. The phase compensation circuit generates a second current Is corresponding to the gate voltage of the output transistor and supplies the second current to an output terminal of the operational amplifier.

As will be described in detail below, the second current Is is a current corresponding to the first current Ir, and therefore is a current corresponding to a variation (an AC component) of the output voltage Vout.

The phase compensation circuit further generates a third current Ifb corresponding to the second current Is, in other words, corresponding to a variation of the output voltage Vo. The phase compensation circuit feeds back the third current Ifb to the active load to change a balance of the current mirror circuit. That is, the phase compensation circuit performs phase compensation in a current-feedback manner.

The above describes a configuration of the operational amplifier according to the embodiment. Next, an operation thereof will be described in the frequency domain.

Consider a case in which the operational amplifier configures a non-inverting amplifier as shown in FIG. 2. A closed-loop gain G(s) of the non-inverting amplifier is expressed by Equation (1):

G(s)=Vo(s)/Vin(s)=Av(s)/(1+βAv(s)) (1)
Here, Av(s) is an open-loop gain of the operational amplifier, and β is a feedback factor.

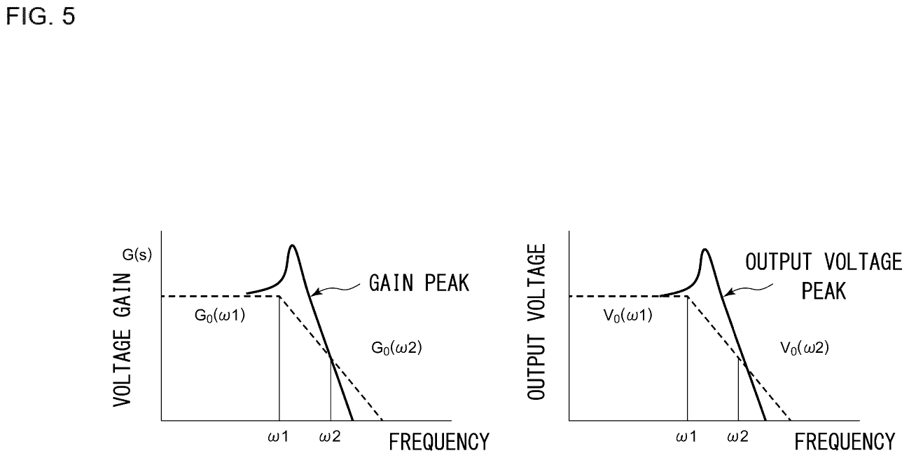

FIG. 5 is a diagram showing frequency characteristics of a conventional non-inverting amplifier. FIG. 5 shows a closed-loop gain G(s) of the non-inverting amplifier and frequency characteristics of an output voltage Vo. A broken line indicates the gain G(s) when no load is connected, and a solid line indicates the gain G(s) when a large load capacitance is connected, showing that the non-inverting amplifier has a gain peak depending on the load capacitance. When an angular frequency changes from a first pole ω1 to a second pole ω2, the closed-loop gain changes from Go(ω1) to Go(ω2).

By transforming Equation (1), an output voltage Vo(s) is expressed by Equation (2):

Vo(s)=Av(s)/(1+βAv(s))×Vin(s) (2)
where s=jω.

When an amplitude of the input voltage Vin is constant, frequency characteristics of the output voltage Vo(s) follow the frequency characteristics of the closed-loop gain G(s). Therefore, in a frequency domain, the output voltage Vo(s) has a gain peak, and when the angular frequency changes from ω1 to ω2, the output voltage Vo(s) changes from Vo(ω1) to Vo(ω2).

A first current Ir(s) flowing through the output variation detection circuit is expressed as:

Ir(s)=(1/Ro)×Vo(s)
As described above, since the output voltage Vo(s) follows the closed-loop gain G(s) of the non-inverting amplifier, the first current Ir(s) also follows the closed-loop gain G(s) of the non-inverting amplifier.

As can be seen from FIG. 3, a steep decrease in gain and a rapid rotation of phase occur in the same frequency band. Accordingly, the first current Ir(s) represents a change in the closed-loop gain G(s), and furthermore, it can be said that the first current Ir(s) represents a phase rotation.

When the first current Ir(s) increases, an output current Io of the output stage increases. When a bias current of the output stage is Ib and a drain current of the output transistor is Im5, a relationship of Io=Ib−Im5 is satisfied. Accordingly, as the first current Ir(s) increases, the drain current Im5 decreases, and as the first current Ir(s) decreases, the drain current Im5 increases.

The drain current Im5 of the output transistor increases as a gate voltage Vm increases, and decreases as the gate voltage Vm decreases. The phase compensation circuit generates a second current Is based on the gate voltage Vm of the output transistor so as to follow a change in an output current of the input stage. That is, since the second current Is has an amount corresponding to the first current Ir, part or all of the first current Ir is canceled by the second current Is.

The phase compensation circuit further generates a third current Ifb corresponding to the second current Is. The third current Ifb also has an amount corresponding to the first current Ir. As described above, the first current Ir represents the closed-loop gain G(s) of the non-inverting amplifier.

When the third current Ifb is fed back to the active load, the gate voltage Vm of the output transistor increases, and the output current Io decreases. That is, in the operational amplifier, when a gain peak is detected by the output variation detection circuit, negative feedback is applied such that an increase in the output voltage Vo is suppressed by the third current Ifb.

As described above, according to the operational amplifier, a gain peak caused by a capacitive load Co can be suppressed.

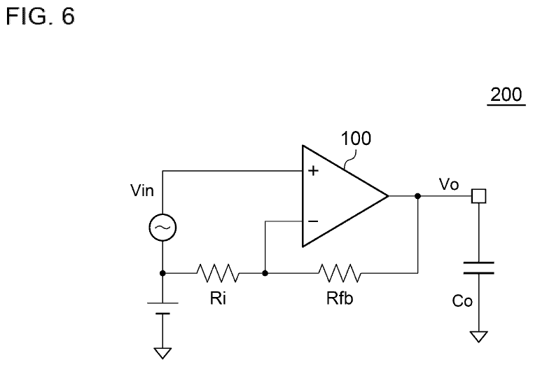

FIG. 6 is a circuit diagram of a non-inverting amplifier using the operational amplifier. The non-inverting amplifier includes the operational amplifier and resistors Ri and Rfb.

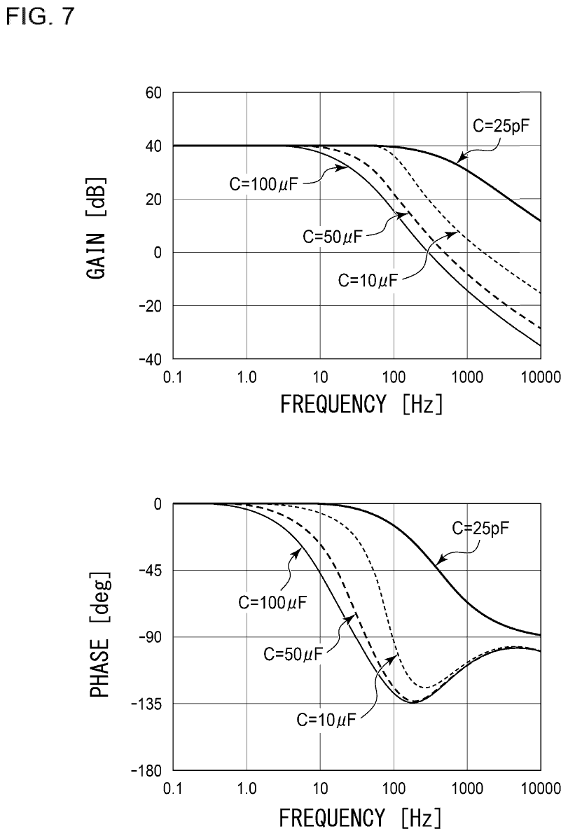

FIG. 7 is a diagram showing frequency characteristics of the non-inverting amplifier of FIG. 6. The frequency characteristics are calculated with Ri=1 kΩ and Rfb=100 kΩ.

As shown in FIG. 3, in a conventional technique, a gain peak occurs in gain characteristics when a large load capacitance Co is connected. In contrast, when the operational amplifier according to the embodiment is used, the gain peak can be suppressed. Further, focusing on phase characteristics, in the conventional technique, a steep phase rotation occurs due to the load capacitance Co, whereas in the embodiment, even when a large load capacitance Co of 100 μF is connected, a phase lag is suppressed to 135°, indicating that sufficient phase margin is obtained.

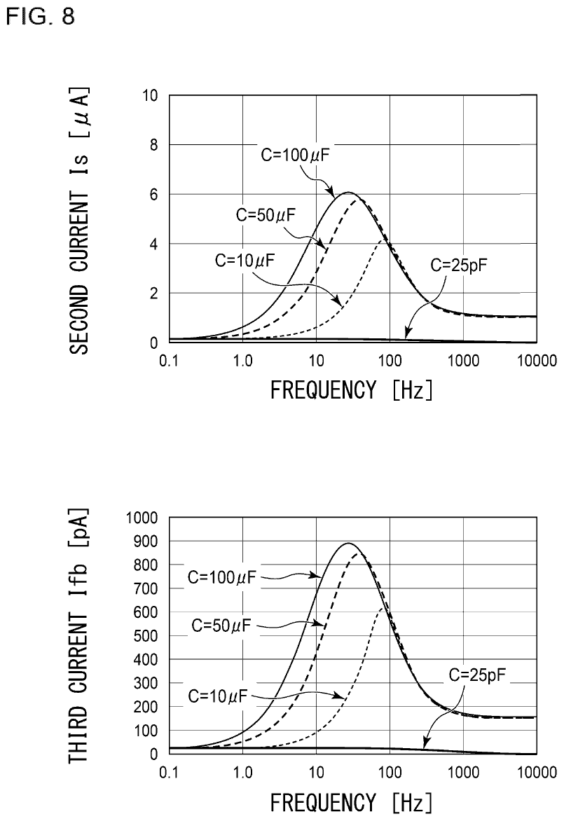

FIG. 8 is a diagram showing frequency characteristics of the second current Is and the third current Ifb. It can be seen that the second current Is and the third current Ifb have the same frequency characteristics. An amount of the third current Ifb may be appropriately designed so as to obtain suitable phase compensation.

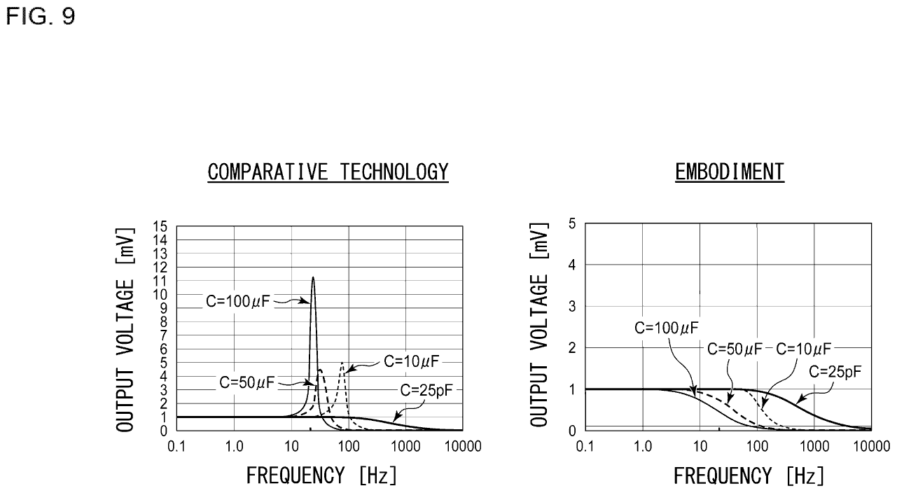

FIG. 9 is a diagram showing frequency characteristics of an output voltage of a non-inverting amplifier according to a comparative technique and a non-inverting amplifier according to the embodiment. In the comparative technique, a gain peak occurs depending on a load capacitance, whereas in the embodiment, the gain peak is suppressed regardless of a magnitude of the load capacitance.

The present disclosure extends to various apparatuses and methods that can be understood from the circuit diagram of FIG. 4 or derived from the above description, and is not limited to specific configurations. Hereinafter, in order not to narrow the scope of the present disclosure, but to assist in understanding and clarifying the essence and operation of the present disclosure, more specific configuration examples and embodiments will be described.

### Embodiment 1

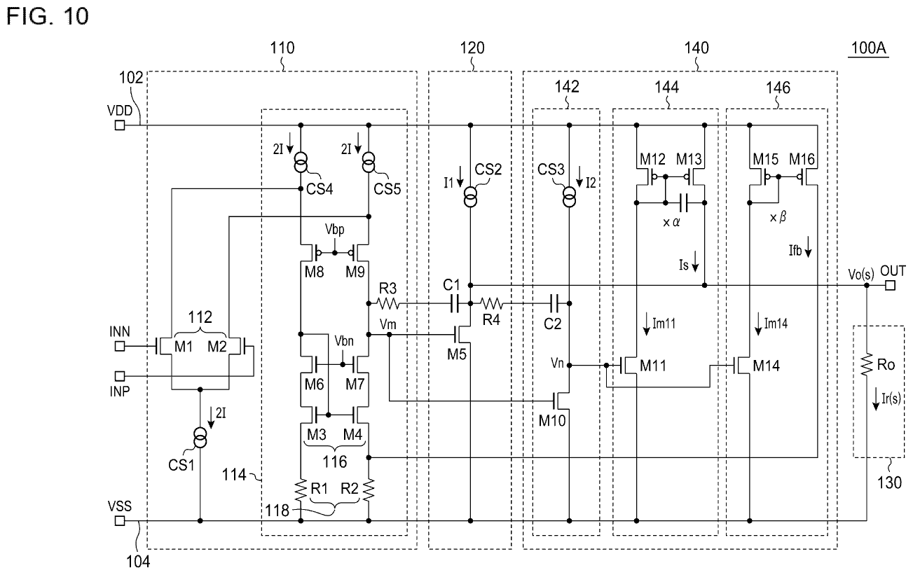

FIG. 10 is a circuit diagram of an operational amplifier 100A according to Embodiment 1. The operational amplifier 100A is a folded-cascode operational amplifier. A differential pair 112 of the input stage 110 includes N-channel MOSFETs (PMOS transistors) M1 and M2. In addition to NMOS transistors M3 and M4 forming a current mirror circuit 116 and resistors R1 and R2 forming an impedance circuit 118, the active load 114 further includes current sources CS4 and CS5, NMOS transistors M6 and M7, and PMOS transistors M8 and M9. A gate of each NMOS transistor M6 and M7 is supplied with a bias voltage Vbn generated by a bias circuit (not shown), and a gate of each PMOS transistor M8 and M9 is supplied with a bias voltage Vbp generated by a bias circuit (not shown).

The output stage 120 is an A-class output stage and includes an output transistor M5 and a current source CS2. A capacitor C1 and a resistor R3 constitute a phase-compensation circuit.

The output-voltage monitoring circuit 130 includes a resistor Ro connected between an output terminal OUT and the ground line 104. The output-voltage monitoring circuit 130 sinks a first current Ir represented by Ir=Vo/Ro.

The phase-compensation circuit 140 includes a replica output stage 142, a second current generation section 144, and a third current generation section 146. The replica circuit 142 includes a transistor M10 (called a replica transistor) and a current source CS3, and has the same circuit configuration as the output stage 120. A gate of the transistor M10 receives the same voltage Vm as a gate voltage Vm of the output transistor M5. Accordingly, the replica circuit 142 operates in the same manner as the output stage 120. The replica circuit 142 outputs a drain voltage Vn of the transistor M10.

The second current generation section 144 includes an NMOS transistor M11 and PMOS transistors M12 and M13. A gate of the NMOS transistor M11 receives the output voltage Vn of the replica circuit 142. The PMOS transistors M12 and M13 form a current mirror circuit, fold back a current Im11 flowing through the NMOS transistor M11, and generate the second current Is by multiplying the current Im11 by a constant (α times).

The third current generation section 146 is configured in the same manner as the second current generation section 144. Specifically, the third current generation section 146 includes an NMOS transistor M14 and PMOS transistors M15 and M16. A gate of the NMOS transistor M14 receives the output voltage Vn of the replica circuit 142. The PMOS transistors M15 and M16 form a current mirror circuit, fold back a current Im14 flowing through the NMOS transistor M14, and generate the third current Ifb by multiplying the current Im14 by a constant (β times). Preferably, the second current generation section 144 is configured such that a current-gain factor β is adjustable.

Specifically, a gate width-to-length ratio (W/L) of the transistor M16 may be adjustable.

The third current Ifb is supplied to the impedance circuit 118. Specifically, the third current Ifb is supplied to a node connecting a source of the NMOS transistor M4 and the resistor R2.

The configuration of the operational amplifier 100A has been described above. Next, operation thereof will be described.

Let resistance values of the resistors R1 and R2 be equal to R. Gate voltages Vg of the transistors M3 and M4 are expressed as follows:

Vg=Vgs3+I·R

Vg=Vgs4+(I+Ifb)·R
where Vgs3 represents a gate-to-source voltage of the transistor M3 and Vgs4 represents a gate-to-source voltage of the transistor M4.

Since the transistors M3 and M4 form a current mirror circuit, when the third current Ifb is not present, Vgs3=Vgs4 holds. However, when the third current Ifb is non-zero, the following relationship is established:

Vgs4=Vgs3−Ifb×R
That is, the gate-to-source voltage Vgs4 of the transistor M4 becomes smaller due to the third current Ifb fed back thereto. In other words, when a gain peak occurs at a certain frequency ω and the third current Ifb flows, the gate-to-source voltage Vgs4 of the transistor M4 decreases, and a negative feedback is applied. As a result, the gate voltage Vm5 of the output transistor M5 increases, and the output current Io of the output stage 120 decreases, thereby canceling an increase in the output voltage Vo due to the gain peak.

It is noted that the frequency characteristics shown in FIG. 7 were calculated using the operational amplifier 100A of FIG. 10.

### Embodiment 2

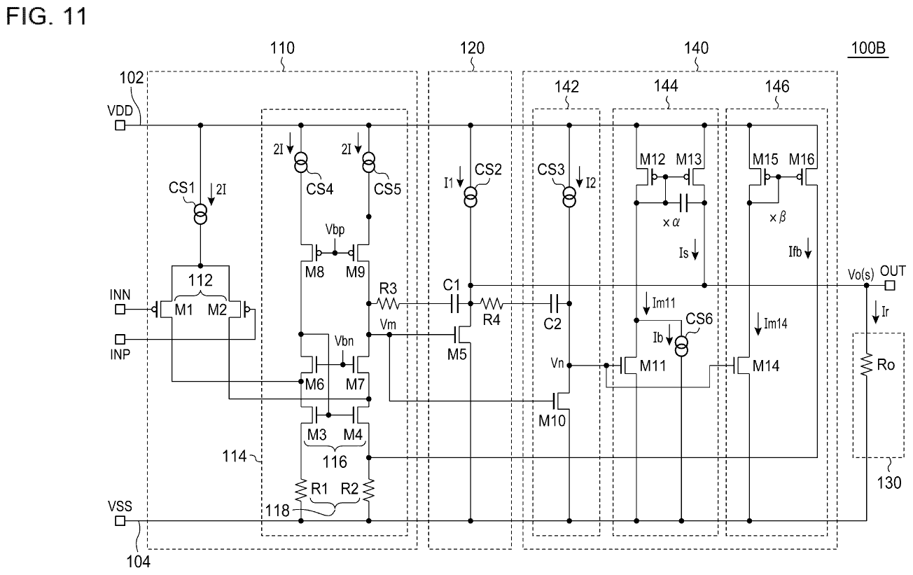

FIG. 11 is a circuit diagram of an operational amplifier 100B according to Embodiment 2. In Embodiment 1, the differential pair 112 (M1 and M2) of the input stage 110 was formed of NMOS transistors. In Embodiment 2, however, the differential pair is formed of PMOS transistors. The active load 114, the replica circuit 142, and the third current generation section 146 are the same as those of FIG. 10. A current source CS6 for sinking a constant current Ib is additionally provided in the second current generation section 144.

Thus, the configuration of the operational amplifier does not depend on whether it is a P-input type or an N-input type.

### Embodiment 3

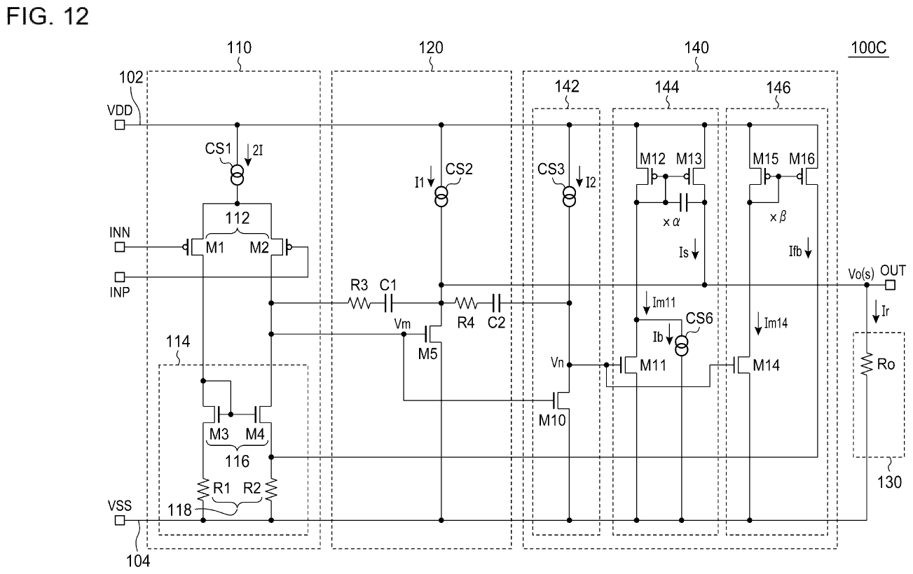

FIG. 12 is a circuit diagram of an operational amplifier 100C according to Embodiment 3. FIGS. 10 and 11 show folded-cascode operational amplifiers, whereas in FIG. 12, the active load 114 is constituted by a current-mirror load. As in FIG. 11, the differential pair 112 is formed of PMOS transistors, and the active load 114 is additionally provided with the current source CS6.

### Embodiment 4

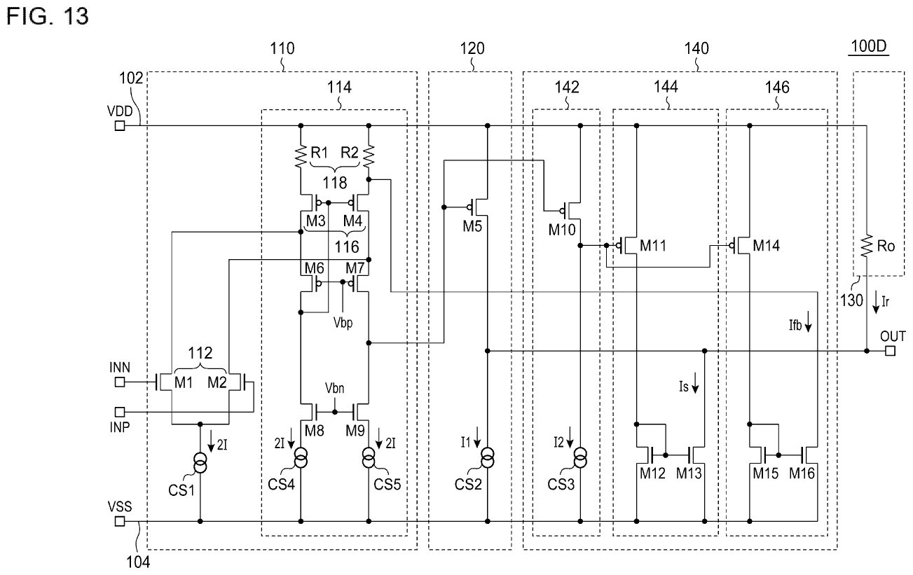

FIG. 13 is a circuit diagram of an operational amplifier 100D according to Embodiment 4. The operational amplifier 100D is obtained by replacing the PMOS transistors of the operational amplifier 100A in FIG. 10 with NMOS transistors, replacing the NMOS transistors with PMOS transistors, and inverting the supply rails (VDD and VSS).

Note that the phase-compensation elements are omitted from illustration.

### Embodiment 5

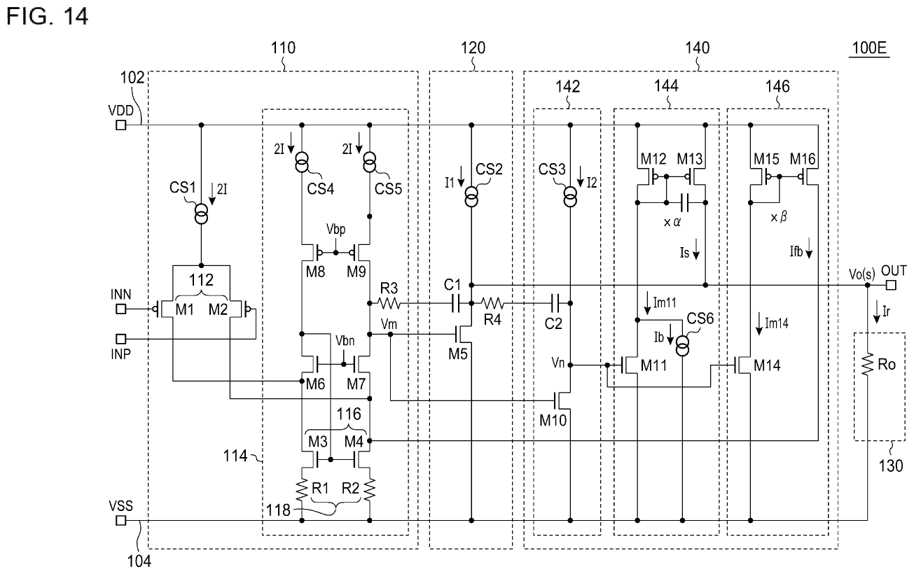

FIG. 14 is a circuit diagram of an operational amplifier 100E according to Embodiment 5. The operational amplifier 100E is configured similarly to the operational amplifier 100B of FIG. 11. A difference from FIG. 11 lies in a supply destination of the third current Ifb generated by the third current generation section 146. In FIG. 14, the third current Ifb is supplied to a drain side of the transistor M4 forming the current mirror circuit 116.

### Embodiment 6

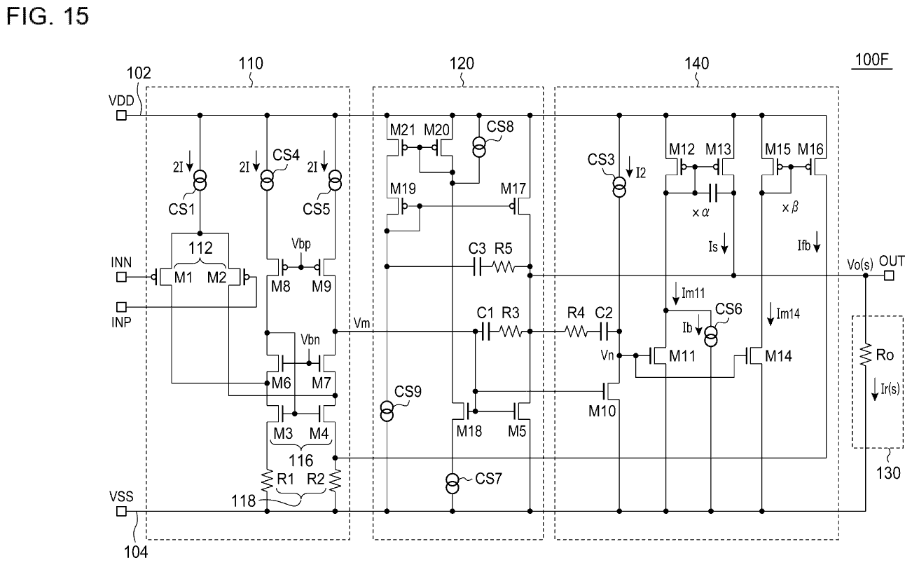

FIG. 15 is a circuit diagram of an operational amplifier 100F according to Embodiment 6. In the above description, A-class operational amplifiers have been described. However, the technology according to the present disclosure is also applicable to AB-class operational amplifiers. The configurations of the input stage 110 and the phase-compensation circuit 140 are the same as those in FIG. 11, while the configuration of the output stage 120 is different from that in FIG. 11.

The output stage 120 is similar to a general AB-class output stage, and includes, in addition to the output transistor M5, transistors M17 to M21 and current sources CS7, CS8, and CS9. Further, for phase compensation, the output stage includes capacitors C1 and C3, and resistors R3 and R5.

### Embodiment 7

As described above, the first current Ir generated by the output variation detection circuit includes not only an AC (alternating-current) component in which a gain peak occurs but also a DC (direct-current) component. Accordingly, the third current Ifb also includes a DC component Ifb(dc) in addition to an AC component Ifb(ac) that contributes to phase compensation. This DC component Ifb(dc) causes a DC offset in the operational amplifier.

In Embodiment 7, a technique for suppressing this DC offset will be described.

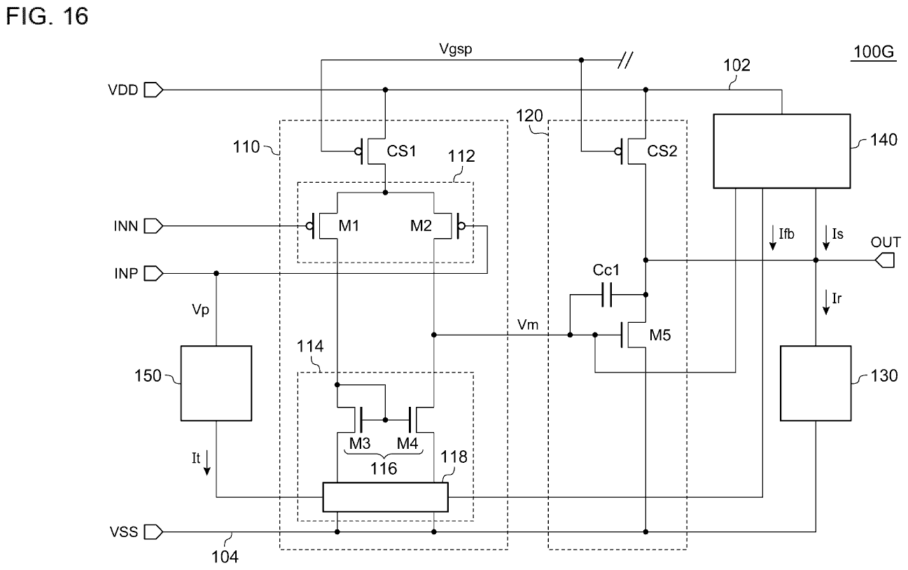

FIG. 16 is a circuit diagram of an operational amplifier 100G according to Embodiment 7. The operational amplifier 100G includes an input stage, an output stage, an output variation detection circuit, and a phase compensation circuit, and further includes an offset cancellation circuit. The offset cancellation circuit supplies, to an impedance circuit of the input stage, a correction current It corresponding to an input voltage (a common-mode input voltage) Vp of the operational amplifier 100G.

The correction current It is supplied to the impedance circuit so as to cancel the third current Ifb generated by the phase compensation circuit.

As shown in FIG. 10, when the third current Ifb is sourced to a source node of a transistor M4 of the current mirror circuit, the correction current It may be sourced to a source node of a transistor M3 of the current mirror circuit.

As shown in FIG. 13, when the third current Ifb is sunk from a source node of a transistor M4 of the current mirror circuit, the correction current It may be sunk from a source node of a transistor M3 of the current mirror circuit.

As shown in FIG. 14, when the third current Ifb is sourced to a drain node of a transistor M4 of the current mirror circuit, the correction current It may be sourced to a drain node of a transistor M3 of the current mirror circuit.

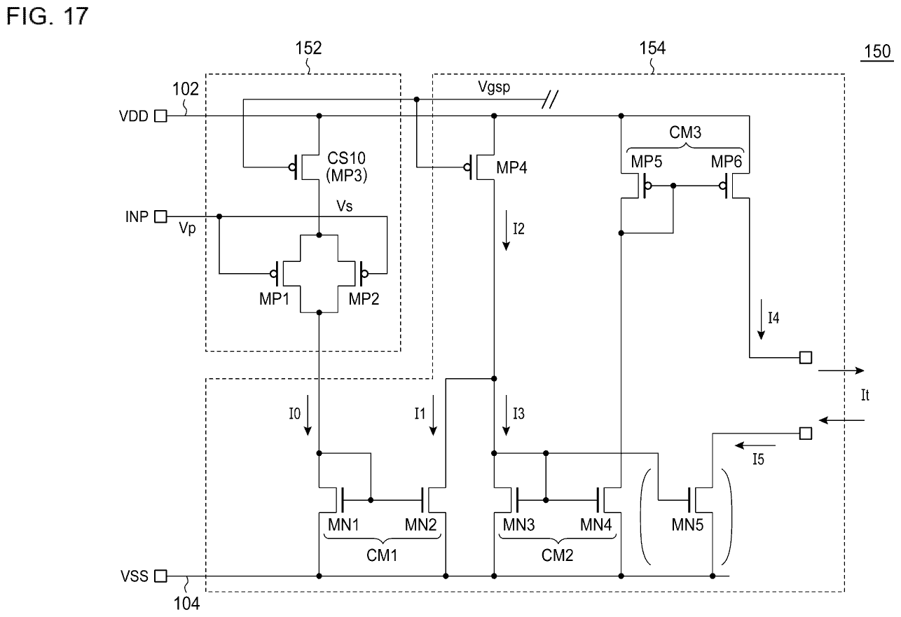

FIG. 17 is a circuit diagram of an offset cancellation circuit according to one embodiment. The offset cancellation circuit includes a common-mode voltage detection circuit and a correction current generation circuit. The common-mode voltage detection circuit converts an input voltage Vp of the operational amplifier into a current signal I₀.

The common-mode voltage detection circuit includes MOS transistors MP1 and MP2 of the same type as the differential pair of the operational amplifier 100G, which are PMOS transistors in this example. Sources of the MOS transistors MP1 and MP2 are commonly connected, and drains thereof are also commonly connected. A voltage Vp of a non-inverting input terminal (INP) of the operational amplifier 100G is input to gates of the MOS transistors MP1 and MP2.

A current source CS10 is connected to the sources of the MOS transistors MP1 and MP2. Sizes of the MOS transistors MP1 and MP2 are equal to sizes of the differential pair, and the current source CS10 generates the same amount of current as the tail current source CS1. The current source CS10 includes a PMOS transistor MP3. A gate of the PMOS transistor MP3 is supplied with a bias voltage Vgsp common to the tail current source CS1.

When an input voltage (a common-mode input voltage) Vp changes, a source voltage Vs of the MOS transistors MP1 and MP2, in other words, a drain-to-source voltage of the PMOS transistor MP3, changes. Due to a channel length modulation effect, a current I₀ flowing through the PMOS transistor MP3 changes with a substantially constant slope in accordance with the input voltage Vp.

The correction current generation circuit generates a correction current It corresponding to the current I₀. The correction current It changes with a substantially constant slope with respect to the input voltage Vp.

The correction current generation circuit includes current mirror circuits CM1, CM2, and CM3, and a current source CS11. The current source CS11 generates a constant current I₂ and includes a PMOS transistor MP4. A gate of the PMOS transistor MP4 is supplied with a bias voltage Vgsp. A size (W/L) of the PMOS transistor MP4 is equal to a size (W/L) of the PMOS transistor MP3.

The current mirror circuit CM1 includes NMOS transistors MN1 and MN2. The current mirror circuit CM1 mirrors the current I₀ and outputs a current I₁.

The current mirror circuit CM2 mirrors a difference current I₃ between the currents I₂ and I₁. The current mirror circuit CM2 includes NMOS transistors MN3 and MN4. The current mirror circuit CM3 mirrors an output current of the current mirror circuit CM2 and outputs a current I₄. The current I₄ is proportional to the current I₃.

I₄=I₃×γ₁
Here, γ₁ is a constant determined by a mirror ratio (a current gain) of the current mirror circuits CM2 and CM3. The correction current generation circuit can source the current I₄, as the correction current It, to the active load.

Instead of transistors MN4, MP5, and MP6, or in addition thereto, an NMOS transistor MN5 may be provided. The NMOS transistor MN5, together with the NMOS transistor MN3, constitutes the current mirror circuit CM2, and a current I₅ proportional to the current I₃ flows through the NMOS transistor MN5.

I₅=I₃×γ₂
Here, γ₂ is a constant determined by a mirror ratio (a current gain) of the current mirror circuit CM2. The correction current generation circuit can sink the current I₅ proportional to the current I₃ from the active load as the correction current It.

The currents I₄ and I₅ may be selectively used, either one or both, depending on a configuration of the input stage.

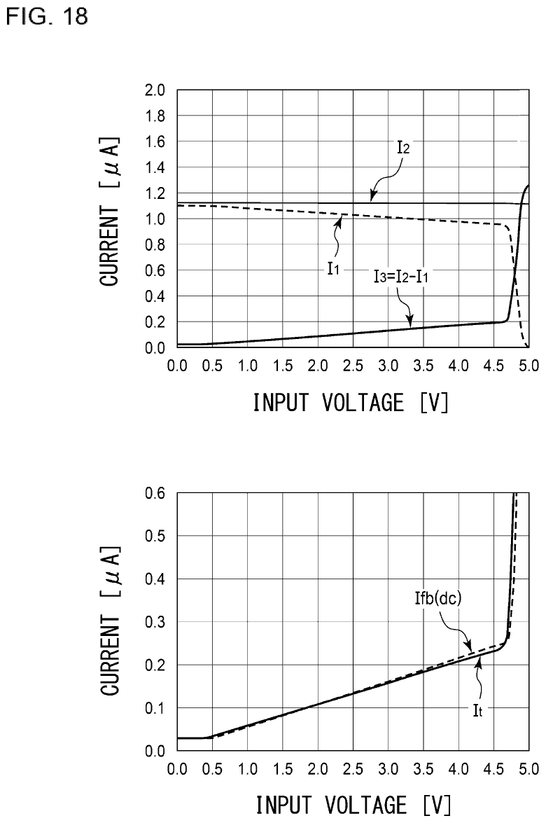

FIG. 18 is a diagram for explaining an operation of the offset cancellation circuit of FIG. 17. An upper diagram shows currents I₁ to I₃ with respect to an input voltage. The current I₁ has a negative slope with respect to the input voltage Vp, and the current I₃ has a positive slope with respect to the input voltage Vp, and increases linearly with a constant slope as the input voltage Vp increases.

A lower diagram of FIG. 18 shows the correction current It and a DC component Ifb(dc) of the third current Ifb generated by the phase compensation circuit. By appropriately setting the current gain γ₁ of the correction current generation circuit, an influence of the DC component Ifb(dc) of the third current Ifb can be canceled. As a result, an offset voltage of the operational amplifier can be suppressed.

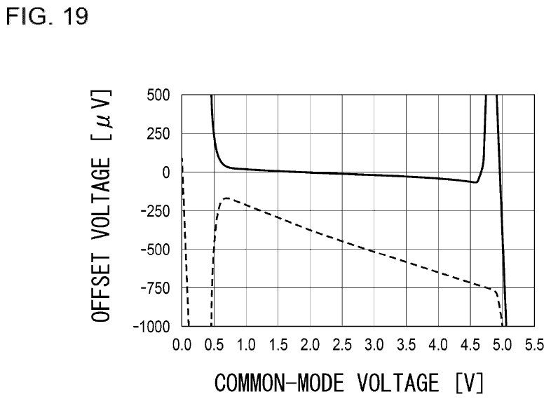

FIG. 19 is a diagram showing a relationship between a common-mode input voltage and an offset voltage of a non-inverting amplifier. A solid line indicates characteristics of a non-inverting amplifier using the operational amplifier 100G of FIG. 16. For comparison, characteristics of a non-inverting amplifier using the operational amplifier of FIG. 4 that does not include the offset cancellation circuit are indicated by a broken line. By providing the offset cancellation circuit, an offset voltage depending on the input voltage can be brought closer to 0 V.

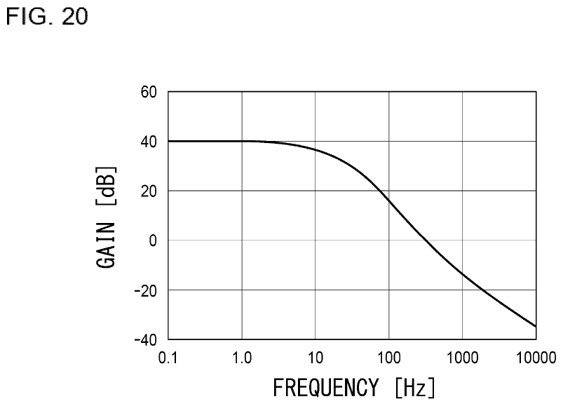

FIG. 20 is a diagram showing frequency characteristics of a non-inverting amplifier using an operational amplifier. A solid line indicates characteristics of a non-inverting amplifier using the operational amplifier 100G of FIG. 16. For comparison, characteristics of a non-inverting amplifier using the operational amplifier of FIG. 4 that does not include the offset cancellation circuit are indicated by a broken line. A load capacitance of 100 μF is connected to the non-inverting amplifier. No degradation in frequency characteristics due to addition of the offset cancellation circuit is observed.

As described above, according to the operational amplifier 100G of FIG. 16, stability with respect to a large load capacitance can be improved while suppressing an offset voltage.

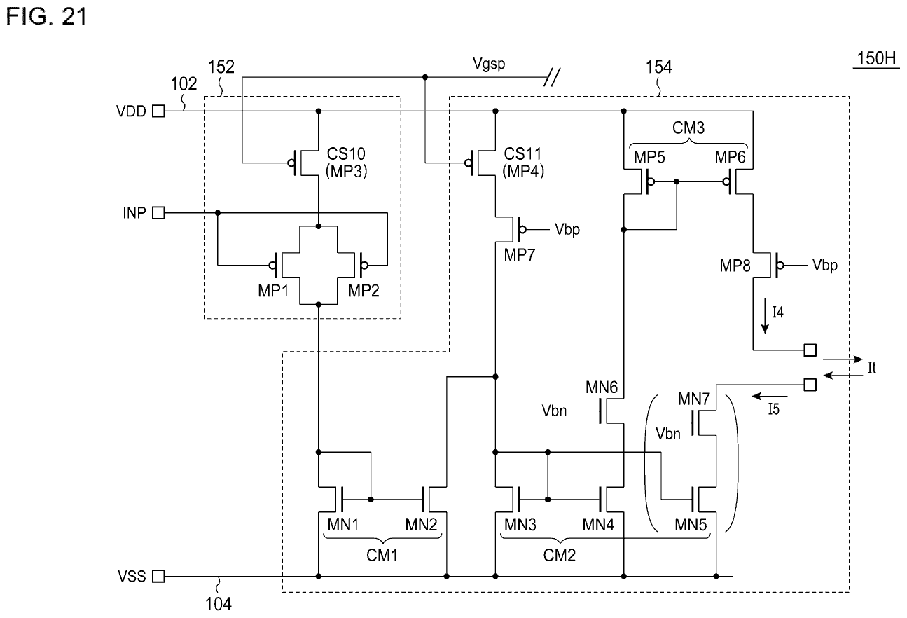

FIG. 21 is a circuit diagram of an offset cancellation circuit 150H according to Modification 1. The offset cancellation circuit 150H differs from that of FIG. 17 in a configuration of the correction current generation circuit. Specifically, in the correction current generation circuit of FIG. 21, PMOS transistors MP7 and MP8 and NMOS transistors MN6 and MN7, which serve as cascode devices, are added. Gates of the respective MOS transistors are supplied with appropriate bias voltages Vbp or Vbn.

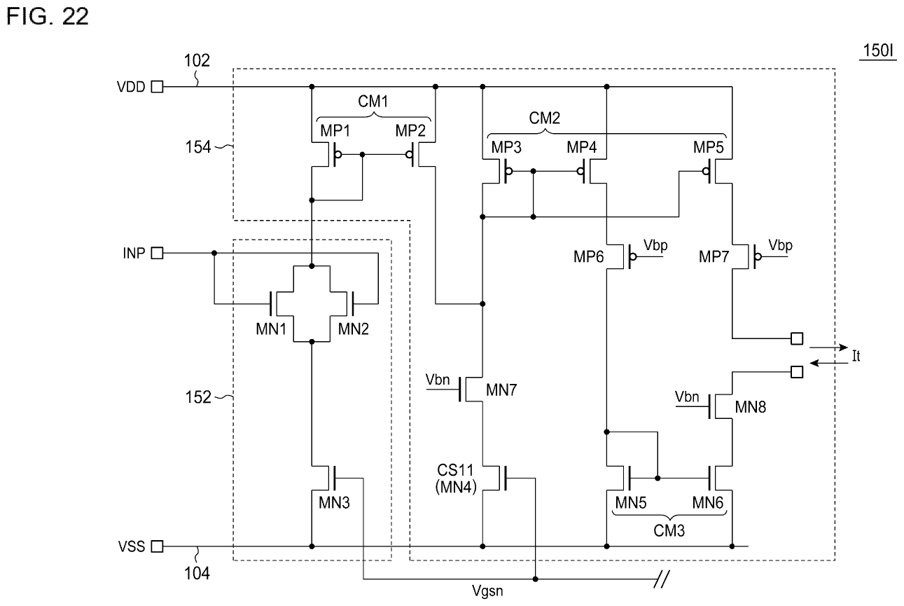

FIG. 22 is a circuit diagram of an offset cancellation circuit 150I according to Modification 2. The offset cancellation circuit 150I is obtained by replacing PMOS transistors of the offset cancellation circuit 150H of FIG. 21 with NMOS transistors, replacing NMOS transistors with PMOS transistors, and inverting upper and lower power supplies (VDD and VSS).

The embodiments merely illustrate the principles and applications of the present disclosure, and numerous modifications and variations of arrangement are allowed within the scope not departing from the spirit of the present disclosure as defined by the claims.

### Appendix

The techniques disclosed in this specification can be understood in one aspect as follows.
Item 1. An operational amplifier, comprising:
   an input stage including a differential pair, a tail current source, and an active load;
an output stage including an output transistor configured to receive an output signal of the input stage;
an output variation detection circuit connected to an output terminal of the operational amplifier and structured to generate a first current corresponding to an output voltage generated at the output terminal; and
a phase compensation circuit structured to supply, to the output terminal, a second current corresponding to a gate voltage of the output transistor, and to supply, to the active load, a third current corresponding to the second current.
Item 2. The operational amplifier of item 1, wherein the active load includes:
a current mirror circuit; and
a pair of resistors connected to a source of the current mirror circuit,
and the third current is supplied to a source side of the current mirror circuit.
Item 3. The operational amplifier of item 1, wherein the active load includes:
a current mirror circuit; and
a pair of resistors connected to a source of the current mirror circuit,
and the third current is supplied to a drain side of the current mirror circuit.
Item 4. The operational amplifier of any one of items 1 to 3, wherein the phase compensation circuit is structured to adjust an amount of the third current with respect to an amount of the second current.
Item 5. The operational amplifier of any one of items 1 to 4, wherein the phase compensation circuit includes:
a replica transistor of the same type as the output transistor, having its gate connected to a gate of the output transistor and having a source grounded; and
a current source connected to a drain of the replica transistor,
and is structured to generate the second current and the third current in accordance with a drain voltage of the replica transistor.
Item 6. The operational amplifier of item 5, wherein the phase compensation circuit includes:
a first transistor having a gate coupled to receive the drain voltage of the replica transistor and having a source grounded; and
a first current mirror circuit structured to mirror a current flowing through the first transistor to generate the second current.
Item 7. The operational amplifier of item 5 or 6, wherein the phase compensation circuit includes:
a second transistor having a gate coupled to receive the drain voltage of the replica transistor and having a source grounded; and
a second current mirror circuit structured to mirror a current flowing through the second transistor to generate the third current.
Item 8. The operational amplifier of any one of items 1 to 7, wherein the output variation detection circuit includes a resistor provided between the output terminal of the operational amplifier and a ground line, or between the output terminal of the operational amplifier and a power supply line.
Item 9. The operational amplifier of any one of items 1 to 8, further comprising an offset cancellation circuit structured to supply, to the active load, a correction current corresponding to an input voltage.
Item 10. The operational amplifier of item 9, wherein the offset cancellation circuit includes:
a common-mode voltage detection circuit structured to convert an input voltage of the operational amplifier into a current signal; and
a correction current generation circuit structured to generate a correction current corresponding to the current signal.
Item 11. The operational amplifier of item 10, wherein the common-mode voltage detection circuit includes:
a first MOS transistor and a second MOS transistor having gates connected to an input terminal of the operational amplifier, sources connected to each other, and drains connected to each other; and
a third MOS transistor connected to the sources of the first MOS transistor and the second MOS transistor and having a gate supplied with a bias voltage common to the tail current source.
Item 12. The operational amplifier of item 10 or 11, wherein the correction current generation circuit includes:
a current mirror circuit having its input connected to drains of the first MOS transistor and the second MOS transistor and structured to mirror a current flowing through the third MOS transistor; and
a constant current source,
and the correction current corresponds to a difference between a current generated by the constant current source and an output current of the current mirror circuit.
Item 13. The operational amplifier of any one of items 1 to 12, wherein the operational amplifier is monolithically integrated on a single semiconductor substrate.

What is claimed is:

1. An operational amplifier comprising:
an input stage having a differential pair, a tail current source, and an active load;
an output stage including an output transistor coupled to receive an output signal of the input stage;
an output variation detection circuit connected to an output terminal of the operational amplifier and structured to generate a first current corresponding to an output voltage generated at the output terminal; and
a phase compensation circuit structured to supply, to the output terminal, a second current corresponding to a gate voltage of the output transistor, and to supply, to the active load, a third current corresponding to the second current.

2. The operational amplifier according to claim 1, wherein the active load comprises:
a current mirror circuit; and
a pair of resistors connected to a source side of the current mirror circuit, and the third current is supplied to the source side of the current mirror circuit.

3. The operational amplifier of claim 1, wherein the active load includes:
a current mirror circuit; and
a pair of resistors connected to a source side of the current mirror circuit, and the third current is supplied to a drain side of the current mirror circuit.

4. The operational amplifier of claim 1, wherein the phase compensation circuit is structured to adjust an amount of the third current with respect to an amount of the second current.

5. The operational amplifier of claim 1, wherein the phase compensation circuit includes:
a replica transistor of the same type as the output transistor, having its gate connected to a gate of the output transistor and having a source grounded; and
a current source connected to a drain of the replica transistor,
and is structured to generate the second current and the third current in accordance with a drain voltage of the replica transistor.

6. The operational amplifier of claim 5, wherein the phase compensation circuit includes:
a first transistor having a gate coupled to receive the drain voltage of the replica transistor and having a source grounded; and
a first current mirror circuit structured to mirror a current flowing through the first transistor to generate the second current.

7. The operational amplifier of claim 5, wherein the phase compensation circuit includes:
a second transistor having a gate coupled to receive the drain voltage of the replica transistor and having a source grounded; and
a second current mirror circuit structured to mirror a current flowing through the second transistor to generate the third current.

8. The operational amplifier of claim 1, wherein the output variation detection circuit includes a resistor provided between the output terminal of the operational amplifier and a ground line, or between the output terminal of the operational amplifier and a power supply line.

9. The operational amplifier of claim 1, further comprising an offset cancellation circuit structured to supply, to the active load, a correction current corresponding to an input voltage.

10. The operational amplifier of claim 9, wherein the offset cancellation circuit includes:
a common-mode voltage detection circuit structured to convert an input voltage of the operational amplifier into a current signal; and
a correction current generation circuit structured to generate a correction current corresponding to the current signal.

11. The operational amplifier of claim 10, wherein the common-mode voltage detection circuit includes:
a first MOS transistor and a second MOS transistor having gates connected to an input terminal of the operational amplifier, sources connected to each other, and drains connected to each other; and
a third MOS transistor connected to the sources of the first MOS transistor and the second MOS transistor, and having a gate supplied with a bias voltage common to the tail current source.

12. The operational amplifier of claim 10, wherein the correction current generation circuit includes:
a current mirror circuit having its input connected to drains of the first MOS transistor and the second MOS transistor and structured to mirror a current flowing through the third MOS transistor; and
a constant current source,
and the correction current corresponds to a difference between a current generated by the constant current source and an output current of the current mirror circuit.

13. The operational amplifier of claim 1, wherein the operational amplifier is monolithically integrated on a single semiconductor substrate.
